(19) United States
(12) Patent Application Publication
(10) Pub. No.: US 2024/0005071 A1
(43) Pub. Date: Jan. 4, 2024

(54) GOVERNOR REALTIME/HARDWARE IN THE LOOP TESTING AND HYDROPOWER PLANT OPERATOR TRAINING

(71) Applicants: Mohammad Durali, Tehran (IR); Seyed Mahdi Hosseini, Tehran (IR); Mohammad Reza Dehghani, Yazd (IR); Mahdi Eskandari, Tehran (IR); Ali Ghorbanpour, Tehran (IR)

(72) Inventors: Mohammad Durali, Tehran (IR); Seyed Mahdi Hosseini, Tehran (IR); Mohammad Reza Dehghani, Yazd (IR); Mahdi Eskandari, Tehran (IR); Ali Ghorbanpour, Tehran (IR)

(73) Assignees: Durali System Design & Automation Co., Tehran (IR); Sharif University of Technology, Tehran (IR)

(21) Appl. No.: 18/346,958

(22) Filed: Jul. 5, 2023

Related U.S. Application Data
(63) Continuation-in-part of application No. PCT/IB2022/050066, filed on Jan. 5, 2022.
(60) Provisional application No. 63/133,793, filed on Jan. 5, 2021.

(51) Int. Cl. G06F 30/28

(52) U.S. Cl. CPC G06F 30/28

(57) ABSTRACT

A system for performing hardware-in-the-loop test of a turbine governor. The system includes a hydropower plant simulation subsystem and a signal interface. The hydropower plant simulation subsystem allows for simulating dynamic and kinematic behaviors of components of a hydropower plant. The hydropower plant simulation subsystem includes a memory having processor-readable instructions stored therein and a processor that accesses the memory and executes the processor-readable instructions, which, when executed by the processor configure the processor to perform a method. The method includes generating a plurality of output signals by solving mathematical models of the components of the hydropower plant for a plurality of inputs. The signal interface allows for communicating the plurality of output signals from the hydropower plant simulation subsystem to the turbine governor.

### CROSS-REFERENCE TO RELATED APPLICATION

This application is a continuation-in-part of PCT/IB2022/050066 filed Jan. 5, 2022, which claims the benefit of priority from pending U.S. Provisional Patent Application Ser. No. 63/133,793, filed on Jan. 5, 2021, and entitled “SIMULATOR FOR HYDROPOWER PLANT WITH FRANCIS TURBINE FOR GOVERNOR REAL-TIME/HARDWARE IN THE LOOP TESTING AND HYDROPOWER PLANT OPERATOR TRAINING,” which are both incorporated herein by reference in their entirety.

### TECHNICAL FIELD

The present disclosure relates to systems and methods for simulating hydropower plants. Particularly, the present disclosure relates to systems and methods for hydropower plant governor real time/hardware-in-the-loop testing. More particularly, the present disclosure relates to systems and methods for hydropower plant operators training.

### BACKGROUND

Hydroelectric power plants may be utilized for supplying a part of energy demand, as well as, controlling the grid balance, frequency control, and grid management. Governors may refer to devices that control the operation of a power plant and may be responsible for maintaining the safety of a power plant under various working conditions, such as water hammering and load rejection. Consequently, designing, manufacturing, testing, and commissioning governors may be considered very sensitive tasks in overall design of a hydroelectric power plant.

A standard procedure for developing a governor includes testing the designed governor to check the behavior of the governor over a wide range of operating conditions, and further to adjust the control coefficients of the governor before the governor could be installed in the real plant. To this end, a hardware-in-the-loop test may be performed on a completed governor, where the completed governor may be connected to a simulator of the plant. Improving the accuracy of the plant simulation may lead to shorter installation times and lower plant start up risks. There is, therefore, a need for systems and methods that may allow for a more accurate simulation of hydroelectric power plants, and in turn, may allow for a more efficient testing of governors and controllers that are to be installed in real hydroelectric power plants.

Furthermore, since operational errors in hydropower plant may have severe and burdensome consequences, training the operators before working in a real hydroelectric power plant is significantly important. There is, therefore, a need for a simulation system and method that may allow for an accurate simulation of working conditions in a power plant so that the operators may be trained in a safer simulated environment.

### SUMMARY

This summary is intended to provide an overview of the subject matter of the present disclosure and is not intended to identify essential elements or key elements of the subject matter, nor is it intended to be used to determine the scope of the claimed implementations. The proper scope of the present disclosure may be ascertained from the claims set forth below in view of the detailed description and the drawings.

According to one or more exemplary embodiments, the present disclosure is directed to a system for performing hardware-in-the-loop test of a turbine governor. An exemplary system may include a hydropower plant simulation subsystem that may be configured to simulate dynamic and kinematic behaviors of components of an exemplary hydropower plant. An exemplary hydropower plant simulation subsystem may include at least one processor, and at least one memory that may be coupled to an exemplary processor. An exemplary memory may be configured to store executable instructions to urge an exemplary processor to perform a method. An exemplary method may include generating a plurality of output signals by solving mathematical models of exemplary components of an exemplary hydropower plant for a plurality of inputs. In an exemplary embodiment, an exemplary system may further include a signal interface that may be configured to communicate the plurality of output signals from the hydropower plant simulation subsystem to an exemplary turbine governor.

In an exemplary embodiment, exemplary components of an exemplary hydropower plant may include a dam, a penstock, a waterway, a turbine, a generator, and an electrical network. In an exemplary embodiment, exemplary mathematical models of exemplary components of an exemplary hydropower plant may include a waterway model representing the dynamic and kinematic behaviors of an exemplary dam, an exemplary penstock, and an exemplary waterway, a turbine model representing an exemplary turbine behavior, a generator model representing an exemplary generator behavior, and a network model representing an exemplary electrical network behavior.

In an exemplary embodiment, an exemplary waterway model may include a bond-graph model of an exemplary dam, an exemplary penstock, and an exemplary waterway. In an exemplary embodiment, generating the plurality of output signals by solving the mathematical models comprises generating a first plurality of output signals of the plurality of output signals by solving the bond-graph model for a first plurality of inputs of the plurality of inputs. In an exemplary embodiment, the first plurality of output signals may include a flowrate signal representing the flowrate of a water stream entering an exemplary turbine.

In an exemplary embodiment, an exemplary turbine model may include an extrapolated hill chart of the turbine. An exemplary extrapolated hill chart of the turbine may represent the behavior of an exemplary turbine for wicket gate openings in a range of 0 to 100 percent. In an exemplary embodiment, generating the plurality of output signals by solving the mathematical models further comprises generating a second plurality of output signals of the plurality of output signals by solving the turbine model for a second plurality of inputs of the plurality of inputs. In an exemplary embodiment, the second plurality of output signals may include a pressure signal representing a penstock pressure value and a torque signal representing output torque of an exemplary turbine.

In an exemplary embodiment, generating the plurality of output signals by solving the mathematical models may further include generating a third plurality of output signals of the plurality of output signals by solving an exemplary generator model for a third plurality of inputs of the plurality of inputs. In an exemplary embodiment, the third plurality of output signals may include a speed signal representing the rotational speed of an exemplary turbine and a power signal representing output power of an exemplary generator.

In an exemplary embodiment, generating the plurality of output signals by solving the mathematical models may further include generating a fourth plurality of output signals of the plurality of output signals by running an exemplary network mathematical model for a fourth plurality of inputs of the plurality of inputs. In an exemplary embodiment, the fourth plurality of output signals may include a frequency signal representing the electrical frequency.

In an exemplary embodiment, the first plurality of inputs of the plurality of inputs may include a dam water level and an exemplary penstock pressure. In an exemplary embodiment, the second plurality of inputs of the plurality of inputs may include a wicket gate opening value, an exemplary rotational speed of the turbine, and an exemplary flowrate of a water stream entering an exemplary turbine. In an exemplary embodiment, the third plurality of inputs of the plurality of inputs may include an exemplary output torque of the turbine and an exemplary electrical frequency. In an exemplary embodiment, the fourth plurality of inputs of the plurality of inputs may include a network frequency value.

### BRIEF DESCRIPTION OF THE DRAWINGS

The novel features which are believed to be characteristic of the present disclosure, as to its structure, organization, use and method of operation, together with further objectives and advantages thereof, will be better understood from the following drawings in which a presently exemplary embodiment of the present disclosure will now be illustrated by way of example. It is expressly understood, however, that the drawings are for illustration and description only and are not intended as a definition of the limits of the present disclosure. Embodiments of the present disclosure will now be described by way of example in association with the accompanying drawings in which:

FIG. 1 illustrates a bond-graph model of a pipe, consistent with one or more exemplary embodiments of the present disclosure;

FIG. 2 illustrates an extrapolated R-curve, consistent with one or more exemplary embodiments of the present disclosure;

FIG. 3 illustrates an extrapolated hill chart, consistent with one or more exemplary embodiments of the present disclosure;

FIG. 4 illustrates a bond-graph model of an exemplary waterway, consistent with one or more exemplary embodiments of the present disclosure; and

FIG. 5 illustrates a block diagram of a plant simulator coupled to a hydro electrical governor, consistent with one or more exemplary embodiments of the present disclosure.

FIG. 6 shows a high-level functional block diagram of a computer system, consistent with one or more exemplary embodiments of the present disclosure.

### DETAILED DESCRIPTION

The novel features which are believed to be characteristic of the present disclosure, as to its structure, organization, use and method of operation, together with further objectives and advantages thereof, will be better understood from the following discussion.

The present disclosure is directed to exemplary embodiments of a system and method for simulating a hydropower plant that may be utilized for hardware-in-the-loop testing of power plant governors, as well as training operators in a simulated environment. An exemplary power plant governor must undergo factory acceptance testing, the heart of which is performing a hardware-in-the-loop test. An exemplary system and method may allow for performing a hardware-in-the-loop test with improved accuracy. Such improved accuracy in an exemplary system and method may be achieved by modeling an exemplary power plant by a bond-graph method and simulating the behavior of an exemplary turbine of an exemplary power plant during load rejection and gate closing time. Furthermore, an exemplary system and method may allow for an operator to check the hardware and the software, simultaneously, since an exemplary system and method utilizes real signals similar to real on-site wiring instead of using network and wireless communication during the test. In other words, an exemplary system and method may utilize a real signal interface between an exemplary governor and an exemplary simulator, where the signal interface is set as it will be with a real hydropower plant.

An exemplary system and method for simulating a hydropower plant may further be designed aiming at simulating main components of an exemplary hydropower plant including the governor, as well as the working modes of an exemplary hydropower plant. Such complete simulation of an exemplary hydropower plant and an exemplary controller and governor of an exemplary hydropower plant may allow for utilizing an exemplary system and method for training operators in a fully simulated environment before sending them to operate in a real plant.

Regarding hardware-in-the-loop testing, an exemplary system may include a plant simulator that may be connected to an exemplary governor that is to be tested and tuned. An exemplary plant simulator may include a real-time processing unit that may be configured to run mathematical models of various components of an exemplary hydropower plant and its environment. An exemplary plant simulator may be developed with desired levels of complexity and fidelity based at least in part on complexity of the control algorithms that are to be utilized for controlling an exemplary hydropower plant. Even the most complex and highly specialized plant simulators, while being expensive, cost much less than a plant prototype. An exemplary system may allow for testing and tuning a complete manufactured governor or a part of an exemplary manufactured governor without making real experiments in the real hydropower plant. When a manufactured governor is tested and control parameters of a manufactured governor are tuned, the governor may be mounted in the real hydropower plant, where further tests may be performed on the governor before it is considered satisfactorily complete.

An exemplary real-time processing unit of an exemplary plant simulator may run mathematical models of various components of an exemplary hydropower plant, such as a dam, a waterway, a penstock, a surge tank, a turbine, a generator, and a draft tube. Under hardware-in-the-loop test conditions, a governor may be connected to an exemplary plant simulator. An exemplary plant simulator may be configured to simulate various working scenarios for an exemplary governor, and responses of the governor to those simulated scenarios may be recorded and investigated. Based at least in part on the recorded and investigated responses, an exemplary governor may pass or fail the test.

Regarding operator training, an exemplary system and method may include a plant simulator coupled to a simulated governor. Here, an exemplary system may include a simulated controller based at least in part on a mathematical model of an exemplary governor. Such complete simulation of a hydropower plant may allow for training operators about the main operating modes of an exemplary hydropower plant. An exemplary system may include hardware and user interface units that may resemble real hardware and user-interface units to further improve the training process.

As mentioned in preceding paragraphs, an exemplary system and method for simulating an exemplary hydropower plant may be utilized for either performing a hardware-in-the-loop simulation or as an offline simulator for training and analysis purposes. In the case of hardware-in-the-loop simulation, an exemplary governor is not a part of an exemplary plant simulator, however, in the case of training or analysis simulations, an exemplary governor is included in the model. An exemplary system and method for simulating an exemplary hydropower plant is a versatile system that may be configured to cover a wide range of operating modes and events of an exemplary hydropower plant. In terms of hardware, an exemplary system for simulating an exemplary hydropower plant may be assembled in a large portable industrial cubicle. An exemplary cubicle may include an industrial computer that may function as an exemplary processing unit of an exemplary system, an industrial data logger as a communication interface between an exemplary plant simulator and an exemplary governor, interface relays for equipment protection, connection sockets, and other common equipment used for industrial electrical cubicles.

An exemplary plant simulator may run mathematical models of upstream dam, waterway, penstock, surge tank, turbine, generator, and draft tube to simulate all the dynamic and kinematic behaviors of the aforementioned components of an exemplary hydropower plant. Furthermore, an exemplary system may include a user interface unit that may be configured to receive input from a user regarding the simulation parameters, where exemplary input from an exemplary user may be applied in real time and an exemplary user may see the results of parameter changes in real time.

For training purposes, an exemplary plant simulator may further run mathematical model of an exemplary governor as well. An exemplary mathematical model of an exemplary governor may be simulated as a Proportional-Integral-Derivative (PID) controller. An exemplary governor may control rotational speed and power output of an exemplary turbine by controlling water flow through an exemplary turbine. That is, an exemplary governor may include an exemplary processor that determine water flow through an exemplary turbine which consequently, determines rotational speed and power output of an exemplary turbine. An exemplary processor of a governor may further generate a control signal, which includes opening/closing commands for a flow control mechanism, such as a wicket gate. An exemplary governor may include a governor processing unit and a governor hydraulic unit, where an exemplary governor processing unit may include a digital processor that may run control algorithms and an exemplary hydraulic unit that may function as a control signal amplifier. An exemplary digital processor may further send operating commands to an exemplary wicket gate actuator. An exemplary governor processing unit may implement a speed controller, a load controller, and an opening controller. Such implementation of the aforementioned control modes may be carried out as PID algorithms.

An exemplary plant simulator may include an exemplary processor that may run a bond-graph model of an exemplary waterway of an exemplary hydropower plant. An exemplary bond-graph model may be based on the physics of an exemplary system and may allow for a quick, flawless, simple, and flexible modeling of an exemplary waterway. The basis of bond-graph theory is the principle of energy conversion, where each part of an exemplary system may have an energy conversion. An exemplary state equation of an exemplary waterway may be modeled by utilizing bond-graph theory. In an exemplary bond-graph model, each physical component may behave as an inertia, compliance, resistance, energy source, energy sink, transformer or gyrator. An exemplary bond-graph method may include energy bonds that may link the components and define the energy flow. The energy bonds may include 0-junctions for equal forces and Hunctions for equal flows.

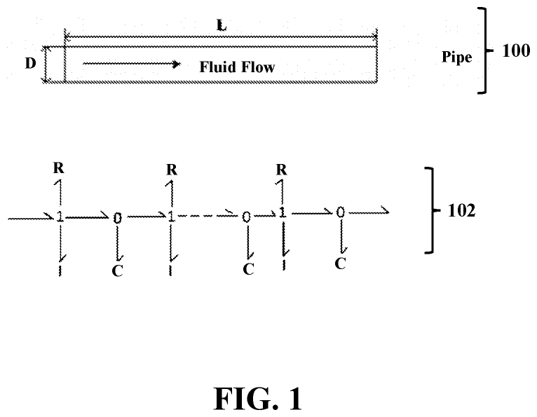

FIG. 1 illustrates a bond-graph model of a pipe, consistent with one or more exemplary embodiments of the present disclosure. In an exemplary embodiment, a pipe 100 with a length of L and a diameter of D is modeled by utilizing bond-graph model. The bond-graph model of pipe 100 is labeled by reference numeral 102. In an exemplary embodiment, parameters of the model may be defined according to Equations (1) to (4) below:

$$I = \frac{ρ L}{A n} \qquad Equation ( 1 )$$

$$C = \frac{A L}{B n} \qquad Equation ( 2 )$$

$$C = \frac{A L}{( B + \frac{D}{t E} ) n} \qquad Equation ( 3 )$$

$$R = f \frac{L}{D} ρ \frac{{Q}^{2}}{2 g {A}^{2}} \qquad Equation ( 4 )$$

In Equations (1) to (4) above, p denotes water density, L denotes pipe length, D denotes pipe diameter, A denotes pipe cross-sectional area, B denotes water bulk module, t denotes pipe wall thickness, E denotes pipe elastic modulus, f denotes Darcy-Weisbach friction factor, g denotes earth gravity, and n denote the number of pipe elements. In an exemplary bond-graph model, all pipes may be segmented and connected together.

An exemplary processor of a plant simulator may further run a model of a turbine. An exemplary turbine may be modeled by utilizing hill diagrams or charts of an exemplary turbine, which are obtained during model tests with an exemplary turbine model performed by the manufacturer. A first step in modeling turbine-generator and wicket gate may be to predict the behavior of an exemplary system over the entire operating range from start-up at zero velocity to velocities above the nominal speed as well as from zero power to powers greater than nominal power. The maximum turbine speed may be the runaway speed of an exemplary turbine, which may be about one and a half to two times the nominal speed of an exemplary turbine. The maximum power may be usually about 120% to 130% of the nominal power of an exemplary unit.

Since manufacturers cannot perform model tests outside the working area of an exemplary turbine (less than 40% of the gate opening), there is a need for extrapolating the hill diagrams of an exemplary turbine outside the working area. To this end, a few principles must be considered. When wicket gate is closed, the flow and power are equal to zero. An exemplary system may work smoothly and without any large gradients. The hydraulic resistance due to the turbine-generator and wicket gate assembly increases rapidly as the wicket gate closes such that it tends to infinity at zero opening. This resistance further depends on the angular velocity of an exemplary turbine, which is a function of the speed and opening of the wicket gate.

In case of a Francis turbine, for extrapolating an exemplary hill chart, the amount of flow and hydraulic resistance on each line in a specific head (e.g., 90 meters) may be calculated with the assumption that the opening lines are linear. Then a flow function and a resistance function may be formulated. According to the behavior of these functions and their extrapolation, the flow and hydraulic resistance for lower openings at a point with a specific head may be obtained. Based on the obtained resistance, the slope of the opening lines may be determined. In addition, knowing the slope of the lines and one of their points (flow), the desired lines may be drawn.

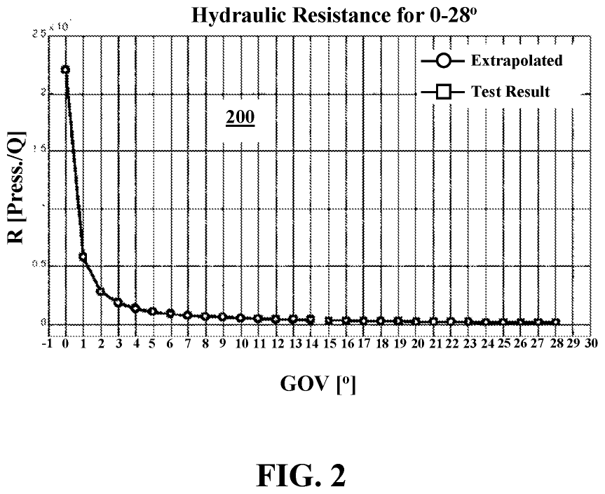

FIG. 2 illustrates an extrapolated R-curve 200, consistent with one or more exemplary embodiments of the present disclosure. In an exemplary embodiment, R-curve 200 may be plotted with respect to different openings and the data for lower openings may be extrapolated as discussed in the preceding paragraph. To extrapolate the points obtained from the experimental hill chart, an extrapolation function or any curve that fits well on these points may be chosen. Then, the resistance, R, for the lower opening points may be estimated utilizing the fitted function.

In an exemplary embodiment, by decreasing the opening rate and water head, the power may be reduced and at zero opening, the power tends to zero for all the heads. It should be noted that the angular velocity of an exemplary turbine may highly affect the turbine torque at lower speeds, such that the higher the torque on the turbine blades, the lower the speed. The maximum torque on the blades occurs when the opening starts from zero. This maximum amount of torque may be determined experimentally and based on the time required for the acceleration of turbine-generator.

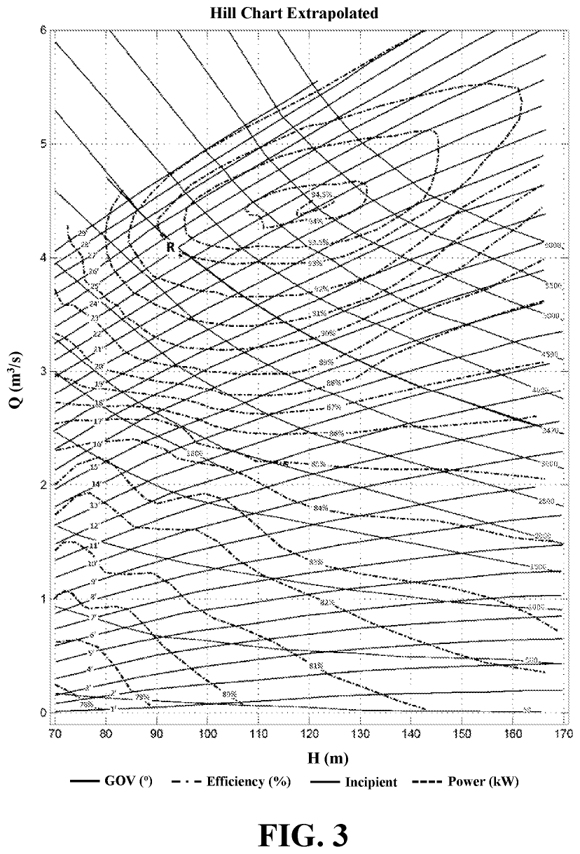

FIG. 3 illustrates an extrapolated hill chart 300, consistent with one or more exemplary embodiments of the present disclosure. In an exemplary embodiment. after obtaining the opening lines and the power lines, the efficiency lines may be calculated and plotted. Efficiency is calculated as power divided by the product of head and flow at a specific point. When hill chart for all opening points is plotted, the inlet water pressure of an exemplary turbine and the opening value at any given point may be obtained. The corresponding flow rate at any given point may as well be obtained from the extrapolated hill chart. These values may be considered as the input for the model of an exemplary water way of an exemplary hydropower plant.

An exemplary bond-graph model of an exemplary waterway may be completed by putting together the bond-graph model of the pipes and the turbine model. When the model is completed, the initial and boundary conditions for all the waterway elements, except the draft tube are stationary. Which means, Qᵢ=0 for all elements and Pᵢ=P₀ for all elements. P₀ is the nominal pressure at 90 m head. For an exemplary draft tube, Q₀ and P₀ are equal to zero. The initial conditions for turbine-generator is stationary, i.e., the velocity and power are equal to zero. The initial conditions for the wicket gate are zero, and its boundary conditions are a constant pressure for the upstream and downstream reservoirs.

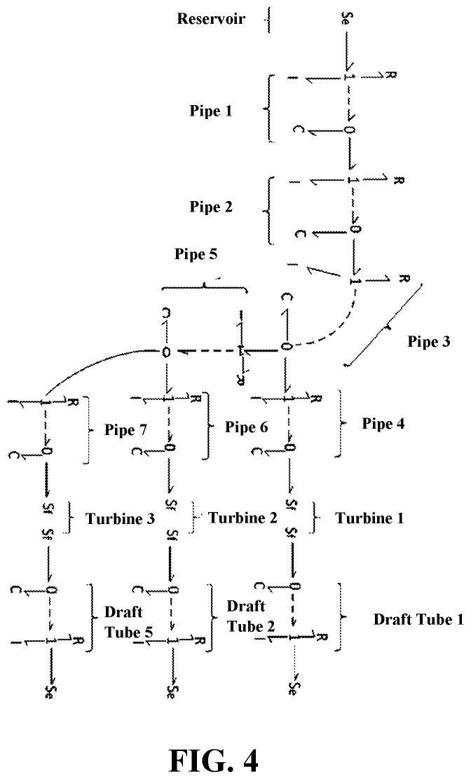

FIG. 4 illustrates a bond-graph model 400 of an exemplary waterway, consistent with one or more exemplary embodiments of the present disclosure. Increasing the number of elements may significantly increase the solving time. However, based on the results of the model, it is evident that the number of elements may have little effect on the accuracy of the output parameters. Consequently, each pipe may be modeled by one element (one mass and one spring). An exemplary pipe may also be divided into two parts and each part may have one element.

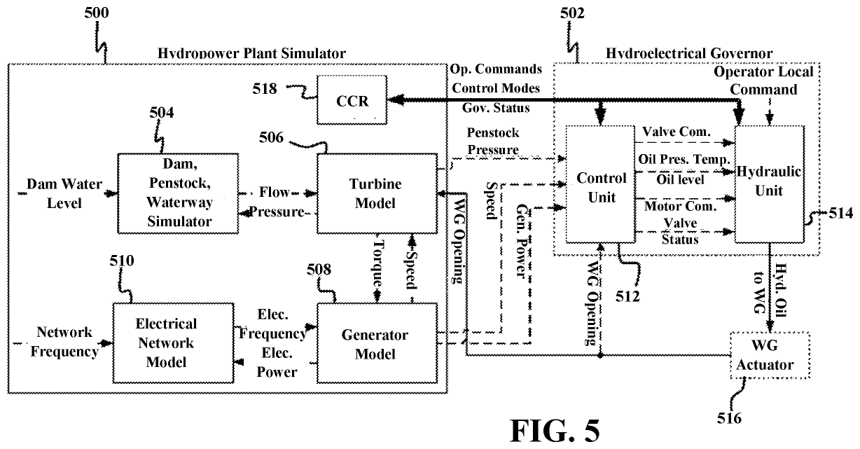

FIG. 5 illustrates a block diagram of a plant simulator 500 coupled to a hydro electrical governor 502, consistent with one or more exemplary embodiments of the present disclosure. As mentioned before, in an exemplary embodiment, an exemplary plant simulator may be utilized for either performing a hardware-in-the-loop simulation or as an offline simulator for training and analysis purposes. In the case of hardware-in-the-loop simulation, hydro electrical governor 502 is not a part of plant simulator 500, however, in the case of training or analysis simulations, hydro electrical governor 502 may be represented by a mathematical model and may be included in plant simulator 500.

In an exemplary embodiment, plant simulator 500 may include at least one processor and at least one memory that may be coupled to the at least one processor. In an exemplary embodiment, the at least one memory may be configured to store executable instructions to urge the at least one processor to generate a plurality of simulation output signals by running mathematical models of components of the hydropower plant for a plurality of simulation inputs. In other words, plant simulator 500 may simulate dynamic and kinematic behaviors of components of a hydropower plant. Therefore, in an exemplary embodiment, plant simulator 500 may be referred to as a “hydropower plant simulator”. In an exemplary embodiment, the components of the hydropower plant may include a dam, a penstock, a waterway, a turbine, a generator, and an electrical network. Consequently, in an exemplary embodiment, plant simulator 500 may include a dam/penstock/waterway simulator 504, a turbine model 506, a generator model 508, and an electrical network model 510 that need to be solved together.

In an exemplary embodiment, dam/penstock/waterway simulator 504 may include one or more processors that may run models that represent the dynamic and kinematic behaviors of the dam, the penstock, and the waterway. As mentioned before, in an exemplary embodiment, dam/penstock/waterway simulator 504 may include a bond-graph model of the dam, the penstock, and the waterway. In an exemplary embodiment, the processor of dam/penstock/waterway simulator 504 may generate a flowrate signal that may represent a flowrate value by running the bond-graph model. In an exemplary embodiment, a dam water level and a downstream pressure must be fed into dam/penstock/waterway simulator 504 as inputs for dam/penstock/waterway simulator 504 to be able to solve the bond-graph model to obtain the flowrate signal. In an exemplary embodiment, the flowrate value may represent the flowrate of a water stream that enters the turbine.

In an exemplary embodiment, turbine model 506 may represent the dynamic and kinematic behavior of an exemplary turbine of an exemplary hydropower plant. In an exemplary embodiment, turbine model 506 may include an extrapolated hill chart of the turbine, the extrapolated hill chart of the turbine representing the behavior of the turbine for wicket gate opening in a range of 0 to 100 percent. For example, turbine model 506 may include an extrapolated hill chart similar to extrapolated hill chart of FIG. 3. In an exemplary embodiment, an extrapolated hill chart of the turbine may determine the relationship between wicket gate opening, flowrate, pressure, and the output torque of the turbine. In an exemplary embodiment, turbine model 506 may be solved to generate a pressure signal representing a penstock pressure value and a torque signal representing output torque of the turbine. In an exemplary embodiment, to solve turbine model 506, the wicket gate opening value, the rotational speed of the turbine, and the flowrate of a water stream entering the turbine may be fed into turbine model 506 as inputs.

In an exemplary embodiment, generator model 508 may represent the behavior of an exemplary generator of an exemplary hydropower plant. In an exemplary embodiment, generator model 508 may be solved to generate a speed signal representing the rotational speed of the turbine and a power signal representing output power of the generator. In an exemplary embodiment, the output torque of the turbine and the electrical frequency may be fed into generator model 508 as inputs in order to obtain the speed signal and the power signal.

In an exemplary embodiment, electrical network model 510 may represent the behavior of an exemplary electrical network. In an exemplary embodiment, electrical network model 510 may be solved utilizing one or more processors to generate a frequency signal representing the electrical frequency. To this end, network frequency value may be fed into electrical network model 510 as an input.

In an exemplary embodiment, hydro electrical governor 502 may include a control unit 512 that may be coupled in signal communication to a hydraulic unit 514. In an exemplary embodiment, control unit 512 may include a proportional-integral-derivative controller, and hydraulic unit 514 may include at least one hydraulic oil reservoir and a hydraulic oil pump that may be coupled in fluid communication with the hydraulic oil reservoir. In an exemplary embodiment, control unit 512 may be configured to receive a plurality of simulation outputs from plant simulator 500. In an exemplary embodiment, the plurality of simulation outputs may include at least one of the pressure signal, the speed signal, and the power signal. In an exemplary embodiment, hydraulic unit 514 may further be coupled to an actuator 516 of the wicket gate of the turbine, where hydraulic unit 514 may further be configured to send hydraulic oil to actuator 516 of the wicket gate of the turbine in response to receiving wicket gate opening commands from control unit 512.

In an exemplary embodiment, plant simulator 500 may further include a user interface unit 518 that may be similar to real interfaces utilized in a hydropower plant control room. In an exemplary embodiment, user interface unit 518 may be configured to receive input data from a user, where input data may include operational commands and selection of control modes. In an exemplary embodiment, user interface unit 518 may further be configured to offer a user four control mode options of speed control mode, power control mode, pressure control mode, and wicket gate opening control mode. In an exemplary embodiment, a user may choose at least one of the aforementioned control modes. In an exemplary embodiment, user interface unit 518 may be coupled in signal communication with control unit 512, where user interface unit 518 may send the user data input to control unit 512.

In an exemplary embodiment, when a user selects the speed control mode, control unit 512 may control the rotational speed of the turbine at a given speed set point by manipulating the opening of the wicket gate of the turbine. In an exemplary embodiment, control unit 512 may be configured to manipulate the opening of the wicket gate of the turbine by sending wicket gate opening commands to hydraulic unit 514. Then, hydraulic unit 514 may be utilized the at least one hydraulic pump of hydraulic unit 514 to pump the hydraulic oil to actuator 516 of the wicket gate of the turbine based at least in part on the received wicket gate opening commands from control unit 512.

In an exemplary embodiment, when a user selects the power control mode, control unit 512 may further be configured to control the output power of the generator at a given power set point by manipulating the opening of the wicket gate of the turbine. In an exemplary embodiment, when a user selects the pressure control mode, control unit 512 may further be configured to control the penstock pressure at a given pressure set point by manipulating the opening of the wicket gate of the turbine. In an exemplary embodiment, when a user selects the wicket gate opening control mode, control unit 512 may further be configured to control the penstock pressure at a given opening set point by manipulating the opening of the wicket gate of the turbine.

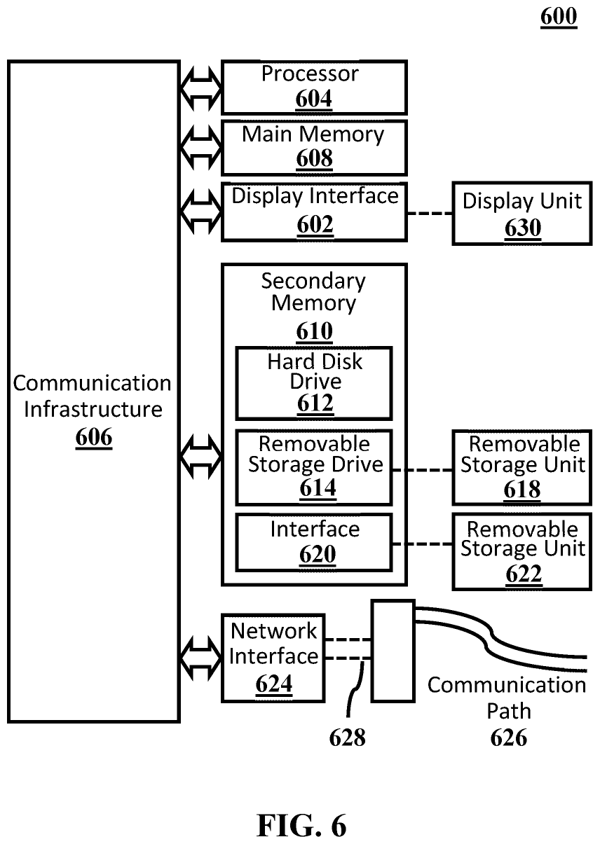

FIG. 6 shows an example computer system 600 in which an embodiment of the present invention, or portions thereof, may be implemented as computer-readable code, consistent with exemplary embodiments of the present disclosure. For example, Equations (1)-(4) and different models and graphs of FIGS. 1-5 may be implemented in computer system 600 using hardware, software, firmware, tangible computer readable media having instructions stored thereon, or a combination thereof and may be implemented in one or more computer systems or other processing systems. Hardware, software, or any combination of such may embody any of the modules and components in FIGS. 1-5.

If programmable logic is used, such logic may execute on a commercially available processing platform or a special purpose device. One ordinary skill in the art may appreciate that an embodiment of the disclosed subject matter can be practiced with various computer system configurations, including multi-core multiprocessor systems, minicomputers, mainframe computers, computers linked or clustered with distributed functions, as well as pervasive or miniature computers that may be embedded into virtually any device.

For instance, a computing device having at least one processor device and a memory may be used to implement the above-described embodiments. A processor device may be a single processor, a plurality of processors, or combinations thereof. Processor devices may have one or more processor “cores.”

An embodiment of the invention is described in terms of this example computer system 600. After reading this description, it will become apparent to a person skilled in the relevant art how to implement the invention using other computer systems and/or computer architectures. Although operations may be described as a sequential process, some of the operations may in fact be performed in parallel, concurrently, and/or in a distributed environment, and with program code stored locally or remotely for access by single or multiprocessor machines. In addition, in some embodiments the order of operations may be rearranged without departing from the spirit of the disclosed subject matter.

Processor device 604 may be a special purpose (e.g., a graphical processing unit) or a general-purpose processor device. As will be appreciated by persons skilled in the relevant art, processor device 604 may also be a single processor in a multi-core/multiprocessor system, such system operating alone, or in a cluster of computing devices operating in a cluster or server farm. Processor device 604 may be connected to a communication infrastructure 606, for example, a bus, message queue, network, or multi-core message-passing scheme.

In an exemplary embodiment, computer system 600 may include a display interface 602, for example a video connector, to transfer data to a display unit 630, for example, a monitor. Computer system 600 may also include a main memory 608, for example, random access memory (RAM), and may also include a secondary memory 610. Secondary memory 610 may include, for example, a hard disk drive 612, and a removable storage drive 614. Removable storage drive 614 may include a floppy disk drive, a magnetic tape drive, an optical disk drive, a flash memory, or the like. Removable storage drive 614 may read from and/or write to a removable storage unit 618 in a well-known manner. Removable storage unit 618 may include a floppy disk, a magnetic tape, an optical disk, etc., which may be read by and written to by removable storage drive 614. As will be appreciated by persons skilled in the relevant art, removable storage unit 618 may include a computer usable storage medium having stored therein computer software and/or data.

In alternative implementations, secondary memory 610 may include other similar means for allowing computer programs or other instructions to be loaded into computer system 600. Such means may include, for example, a removable storage unit 622 and an interface 620. Examples of such means may include a program cartridge and cartridge interface (such as that found in video game devices), a removable memory chip (such as an EPROM, or PROM) and associated socket, and other removable storage units 622 and interfaces 620 which allow software and data to be transferred from removable storage unit 622 to computer system 600.

Computer system 600 may also include a communications interface 624. Communications interface 624 allows software and data to be transferred between computer system 600 and external devices. Communications interface 624 may include a modem, a network interface (such as an Ethernet card), a communications port, a PCMCIA slot and card, or the like. Software and data transferred via communications interface 624 may be in the form of signals, which may be electronic, electromagnetic, optical, or other signals capable of being received by communications interface 624. These signals may be provided to communications interface 624 via a communications path 626. Communications path 626 carries signals and may be implemented using wire or cable, fiber optics, a phone line, a cellular phone link, an RF link or other communications channels.

In this document, the terms “computer program medium” and “computer usable medium” are used to generally refer to media such as removable storage unit 618, removable storage unit 622, and a hard disk installed in hard disk drive 612. Computer program medium and computer usable medium may also refer to memories, such as main memory 608 and secondary memory 610, which may be memory semiconductors (e.g. DRAMs, etc.).

Computer programs (also called computer control logic) are stored in main memory 608 and/or secondary memory 610. Computer programs may also be received via communications interface 624. Such computer programs, when executed, enable computer system 600 to implement different embodiments of the present disclosure as discussed herein. In particular, the computer programs, when executed, enable processor device 604 to implement the processes of the present disclosure, such as the operations in Equations (1)-(4) and different models and graphs illustrated in FIGS. 1-5 discussed above. Accordingly, such computer programs represent controllers of computer system 600. Where an exemplary embodiment of an equation, a model, or a graph is implemented using software, the software may be stored in a computer program product and loaded into computer system 600 using removable storage drive 614, interface 620, and hard disk drive 612, or communications interface 624.

Embodiments of the present disclosure also may be directed to computer program products including software stored on any computer useable medium. Such software, when executed in one or more data processing device, causes a data processing device to operate as described herein. An embodiment of the present disclosure may employ any computer useable or readable medium. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, and optical storage devices, MEMS, nanotechnological storage device, etc.).

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein. It is to be understood that the phraseology or terminology herein is for description and not of limitation, such that the terminology or phraseology of the present specification is to be interpreted by the skilled artisan in light of the teachings and guidance.

The breadth and scope of the present disclosure should not be limited by any of the above-described exemplary embodiments but should be defined only in accordance with the following claims and their equivalents.

Throughout this specification and the claims which follow, unless the context requires otherwise, the word “comprise”, and variations such as “comprises” or “comprising”, will be understood to imply the inclusion of a stated integer or step or group of integers or steps but not to the exclusion of any other integer or step or group of integers or steps.

Moreover, the word “substantially” when used with an adjective or adverb is intended to enhance the scope of the particular characteristic, e.g., substantially planar is intended to mean planar, nearly planar and/or exhibiting characteristics associated with a planar element. Further use of relative terms such as “vertical”, “horizontal”, “up”, “down”, and “side-to-side” are used in a relative sense to the normal orientation of the apparatus.

What is claimed is:

1. A system for performing hardware-in-the-loop test of a turbine governor, the system comprising:
a hydropower plant simulation subsystem configured to simulate dynamic and kinematic behaviors of components of a hydropower plant comprising a dam, a penstock, a waterway, a turbine, a generator, and an electrical network, the hydropower plant simulation subsystem comprising:
a memory having processor-readable instructions stored therein; and
a processor configured to access the memory and execute the processor-readable instructions, which, when executed by the processor configures the processor to perform a method, the method comprising:
generating a first plurality of output signals of a plurality of output signals by solving a bond-graph model for a first plurality of inputs comprising a dam water level and a penstock pressure, the first plurality of output signals comprising a flowrate signal representing a flowrate of a water stream entering the turbine;
generating a second plurality of output signals of the plurality of output signals by solving a turbine model for a second plurality of inputs comprising a wicket gate opening value, a rotational speed of the turbine, and the flowrate of the water stream entering the turbine, the turbine model comprising an extrapolated hill chart representing dynamic and kinematic behaviors of the turbine for wicket gate opening in a range of 0 to 100 percent, the second plurality of output signals comprising a pressure signal representing the penstock pressure value and a torque signal representing output torque of the turbine;
generating a third plurality of output signals of the plurality of output signals by solving a generator model representing dynamic and kinematic behaviors of the generator for a third plurality of inputs comprising the output torque of the turbine and an electrical frequency, the third plurality of output signals comprising a speed signal representing the rotational speed of the turbine and a power signal representing output power of the generator; and
generating a fourth plurality of output signals of the plurality of output signals by running a network mathematical model representing dynamic and kinematic behaviors of the network for a fourth plurality of inputs comprising a network frequency value, the fourth plurality of output signals comprising a frequency signal representing the electrical frequency; and
a signal interface configured to communicate the plurality of output signals from the hydropower plant simulation subsystem to the turbine governor.

2. A method for performing hardware-in-the-loop test of a turbine governor, the method comprising:
simulating, utilizing a hydropower plant simulation subsystem comprising one or more processors, dynamic and kinematic behaviors of components of a hydropower plant, comprising:
generating a plurality of output signals by solving mathematical models of the components of the hydropower plant for a plurality of inputs; and
communicating, utilizing a signal interface, the plurality of output signals from the hydropower plant simulation subsystem to the turbine governor.

3. The method of claim 2, wherein solving the mathematical models comprises:
solving a waterway model representing the dynamic and kinematic behaviors of the dam, the penstock, and the waterway;
solving a turbine model representing the turbine behavior;
solving a generator model representing the generator behavior; and
solving a network model representing the electrical network behavior.

4. The method of claim 3, wherein:
solving the waterway model comprises solving a bond-graph model of the dam, the penstock, and the waterway; and
generating the plurality of output signals by solving the mathematical models comprises generating a first plurality of output signals of the plurality of output signals by solving the bond-graph model for a first plurality of inputs of the plurality of inputs, the first plurality of output signals comprising a flowrate signal representing the flowrate of a water stream entering the turbine.

5. The method of claim 4, wherein:
solving the turbine model comprises solving an extrapolated hill chart of the turbine, the extrapolated hill chart of the turbine representing the behavior of the turbine for wicket gate opening in a range of 0 to 100 percent; and
generating the plurality of output signals by solving the mathematical models further comprises generating a second plurality of output signals of the plurality of output signals by solving the turbine model for a second plurality of inputs of the plurality of inputs, the second plurality of output signals comprising a pressure signal representing a penstock pressure value and a torque signal representing output torque of the turbine.

5. The method of claim 5, wherein generating the plurality of output signals by solving the mathematical models further comprises generating a third plurality of output signals of the plurality of output signals by solving the generator model for a third plurality of inputs of the plurality of inputs, the third plurality of output signals comprising a speed signal representing the rotational speed of the turbine and a power signal representing output power of the generator.

6. The method of claim 5, wherein generating the plurality of output signals by solving the mathematical models further comprises generating a fourth plurality of output signals of the plurality of output signals by running the network mathematical model for a fourth plurality of inputs of the plurality of inputs, the fourth plurality of output signals comprising a frequency signal representing an electrical frequency.

7. The method of claim 6, wherein:
solving the bond-graph model for the first plurality of inputs comprises solving the bond-graph model for a dam water level and the penstock pressure;
solving the turbine model for the second plurality of inputs comprises solving the turbine model for a wicket gate opening value, the rotational speed of the turbine, and the flowrate of a water stream entering the turbine;
solving the generator model for the third plurality of inputs comprises solving the generator model for the output torque of the turbine and the electrical frequency; and
running the network mathematical model for the fourth plurality of inputs comprises running the network mathematical model for a network frequency value.

8. A system for performing hardware-in-the-loop test of a turbine governor, the system comprising:
a hydropower plant simulation subsystem configured to simulate dynamic and kinematic behaviors of components of a hydropower plant, the hydropower plant simulation subsystem comprising:
a memory having processor-readable instructions stored therein; and
a processor configured to access the memory and execute the processor-readable instructions, which, when executed by the processor configures the processor to perform a method, the method comprising:
generating a plurality of output signals by solving mathematical models of the components of the hydropower plant for a plurality of inputs; and
a signal interface configured to communicate the plurality of output signals from the hydropower plant simulation subsystem to the turbine governor.

9. The system of claim 8, wherein solving the mathematical models of the components of the hydropower plant comprises solving mathematical models of a dam, a penstock, a waterway, a turbine, a generator, and an electrical network.

10. The system of claim 9, wherein the mathematical models of the components of the hydropower plant comprise:
a waterway model representing the dynamic and kinematic behaviors of the dam, the penstock, and the waterway;
a turbine model representing the turbine behavior;
a generator model representing the generator behavior; and
a network model representing the electrical network behavior.

11. The system of claim 10, wherein:
the waterway model comprises a bond-graph model of the dam, the penstock, and the waterway; and
generating the plurality of output signals by solving the mathematical models comprises generating a first plurality of output signals of the plurality of output signals by solving the bond-graph model for a first plurality of inputs of the plurality of inputs, the first plurality of output signals comprising a flowrate signal representing the flowrate of a water stream entering the turbine.

12. The system of claim 11, wherein:
the turbine model comprises an extrapolated hill chart of the turbine, the extrapolated hill chart of the turbine representing the behavior of the turbine for wicket gate opening in a range of 0 to 100 percent; and
generating the plurality of output signals by solving the mathematical models further comprises generating a second plurality of output signals of the plurality of output signals by solving the turbine model for a second plurality of inputs of the plurality of inputs, the second plurality of output signals comprising a pressure signal representing a penstock pressure value and a torque signal representing output torque of the turbine.

13. The system of claim 12, wherein generating the plurality of output signals by solving the mathematical models further comprises generating a third plurality of output signals of the plurality of output signals by solving the generator model for a third plurality of inputs of the plurality of inputs, the third plurality of output signals comprising a speed signal representing the rotational speed of the turbine and a power signal representing output power of the generator.

14. The system of claim 13, wherein generating the plurality of output signals by solving the mathematical models further comprises generating a fourth plurality of output signals of the plurality of output signals by running the network mathematical model for a fourth plurality of inputs of the plurality of inputs, the fourth plurality of output signals comprising a frequency signal representing an electrical frequency.

15. The system of claim 14, wherein the first plurality of inputs of the plurality of inputs comprise a dam water level and the penstock pressure.

16. The system of claim 15, wherein the second plurality of inputs of the plurality of inputs comprise a wicket gate opening value, the rotational speed of the turbine, and the flowrate of a water stream entering the turbine.

17. The system of claim 16, wherein the third plurality of inputs of the plurality of inputs comprise the output torque of the turbine and the electrical frequency.

18. The system of claim 17, wherein the fourth plurality of inputs of the plurality of inputs comprise a network frequency value.
